(19) United States
(12) Patent Application Publication
(10) Pub. No.: US 2026/0324099 A1
(43) Pub. Date: Oct. 15, 2026

(54) DOUBLE MULTIPLICATION REGION CONFIGURATION FOR NEAR-INFRARED SENSITIVITY ENHANCE MENT IN SILICON CMOS SINGLE-PHOTON AVALANCHE DIODES

(71) Applicant: Ecole Polytechnique Federale De Lausanne (EPFL), Lausanne (CH)

(72) Inventors: Utku KARACA, Renens (CH); Edoardo CHARBON, JOUXTENS-MEZERY (CH); Claudio BRUSCHINI, Villars-Sous-Yens (CH); Ekin KIZILKAN, Lausanne (CH)

(21) Appl. No.: 19/486,218

(22) PCT Filed: May 21, 2024
(86) PCT No.: PCT/IB2024/054923

§ 371 Date: Nov. 20, 2025

(30) Foreign Application Priority Data
May 22, 2023 (EP) 23174658.7

(51) Int. Cl. H10F 30/225

(52) U.S. Cl. CPC H10F 30/225

(57) ABSTRACT

A near-infrared sensitivity enhanced substrate non-isolated silicon single-photon avalanche diode is disclosed, comprising a p-well layer (101), a high-voltage n-well (102), the p-well layer and the high-voltage n-well layer positioned against each other and configured to form a main junction (100) defining an active area (104), the p-well layer comprising a doping according to a doping concentration distribution, the p-well layer being configured to have first double peaks in its doping concentration distribution throughout the p-well layer in the active area, corresponding to respective p-doped regions, and the high-voltage n-well being configured to have second double peaks, corresponding to respective n-doped regions configured to achieve a n-p-n-p type device junction profile, whereby further the p-well layer is lightly doped and configured to obtain a wide depletion region, i.e., at least 1 μm wide, the high-voltage n-well layer being further configured to extend beyond the p-well layer to form a guard ring (103) around the active area.

### TECHNICAL FIELD

The invention relates to a single-photon avalanche diode, and more precisely, one that addresses the low photon detection probabilities demonstrated at near-infrared (NIR) wavelengths and the high excess bias requirement in the wide depletion (active) region approach while utilizing standard silicon (Si) CMOS technologies.

### BACKGROUND ART

Applications such as light detection and ranging (LiDAR), optical tomography, and fiber optic communications require high-sensitivity photodetection in the near Infrared (NIR) [1]-[3]. Therefore, there has been an increasing effort towards improving NIR efficiency in solid-state photodetectors. In this category of detectors, single-photon avalanche diodes (SPADs) exhibit photon-counting capability and low jitter in a compact and generally low-cost format. In order to enhance sensitivity in the NIR, wider depletion regions have been investigated to be able to collect deeply absorbed NIR photons in silicon [4]-[11]. There are two main challenges in the wide depletion region approach. First, creating a SPAD with a wide depletion region becomes more difficult while shrinking the CMOS technology node since the doping concentrations tend to increase in the reduced dimensions of smaller nodes. Secondly, the electric field magnitude becomes relatively lower in a wide depletion region, and it decays linearly from the avalanche multiplication region towards the edges of the depletion zone. Therefore, wide depletion devices require high excess bias voltages (~10 V) to increase the electric field magnitude and avalanche triggering probability. However, the high excess bias voltage needed might complicate the pixel circuit design when the excess bias becomes higher than the allowed rail-to-rail voltage range in digital circuits.

### SUMMARY OF THE INVENTION

The invention provides a near-infrared sensitivity enhanced substrate non-isolated silicon single-photon avalanche diode, comprising a p-well layer, a high-voltage n-well, the p-well layer and the high-voltage n-well layer positioned against each other and configured to form a main junction defining an active area, the p-well layer comprising a doping according to a doping concentration distribution, the p-well layer being configured to have first double peaks in its doping concentration distribution throughout the p-well layer in the active area, corresponding to respective p-doped regions, and the high-voltage n-well being configured to have second double peaks, corresponding to respective n-doped regions configured to achieve a n-p-n-p type device junction profile, whereby further the p-well layer is lightly doped and configured to obtain a wide depletion region, i.e., at least 1 μm wide, the high-voltage n-well layer being further configured to extend beyond the p-well layer to form a guard ring around the active area.

In a preferred embodiment the n-p-n-p type device junction profile is further configured such that the wide depletion region confines two distinct multiplication regions, and one of the n-doped regions is sandwiched between the p-doped regions, and has a well-designed doping concentration and depth configured such that an electric field between the two p-n junctions never reaches zero.

### BRIEF DESCRIPTION OF THE DRAWINGS

The invention will be better understood through the detailed description of preferred embodiments of the invention, and in reference to the drawings, wherein

FIG. 1 illustrates a cross section of an example embodiment of a device according to the invention;

FIG. 2 contains the electric field profiles of (a) an example embodiment of the device according to the invention with a double multiplication region and (b) a SPAD with a wide depletion region; (c) a graph of electric field comparison illustrating a magnitude of the electric field at the center of each device along a y axis; (d) a schematic illustration of a cross-section of the SPAD with a wide depletion region; wherein white lines on electric field profiles correspond to the depletion region boundaries;

FIG. 3 contains (a) a I-V measurement of the SPAD under ambient light and at room temperature; and (b) light emission tests of the device at 3 V and 5 V excess bias voltages;

FIG. 4 contains a graph of DCR characterization of the device according to the invention, with respect to the excess bias voltage from five different dies;

FIG. 5 contains an inter-arrival avalanche timing histogram with an exponential fit and afterpulsing probability at the excess bias voltage of 5.5 V;

FIG. 6 contains a graph of PDP measurement of the device according to the invention from 1 V to 5.5 V excess bias voltage;

FIG. 7 contains a timing jitter histogram of the device according to the invention, which was obtained at 850 nm and for 5.5 V excess bias voltage;

FIG. 8 contains (a) a graph showing Peak PDP vs. DCR per unit area; and (b) a graph showing PDP at 850 nm vs. excess bias voltage comparisons of the state-of-the-art FSI SPADs fabricated in the same and other CMOS technology nodes;

FIG. 9 contains a graph of a resulting doping profile (n-p-n-p) in doping concentrations represented over a depth;

FIG. 10 indicates the photon absorption at longer wavelengths and avalanche multiplication processes in a wide depletion SPAD with (a) one multiplication region, (b) double multiplication region; and

FIG. 11 illustrates the electron-hole avalanche breakdown probabilities of (a) the example embodiment of the device according to the invention with double multiplication region method, and (b) reference wide depletion region SPAD; (c) values of the avalanche breakdown probabilities at the center of each device along the y axis.

Same references are used to reference the same or similar features throughout the figures.

### DETAILED DESCRIPTION OF PREFERRED EMBODIMENTS OF THE INVENTION

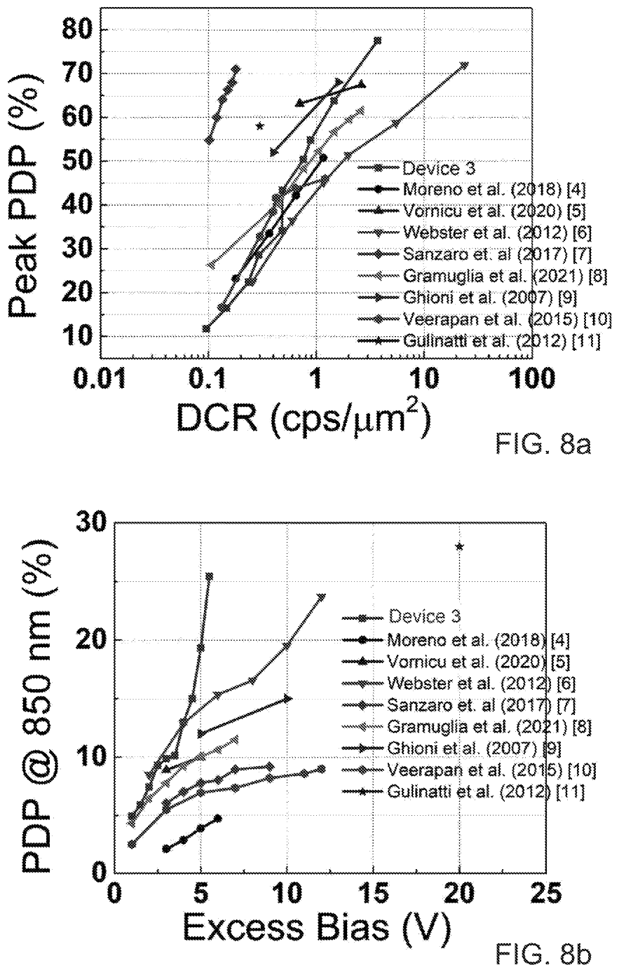

The present invention proposes a SPAD device that addresses low NIR sensitivity and the high excess bias requirement in the wide depletion region approach that is utilized in designing Si CMOS SPADs. The invention demonstrates that higher NIR sensitivities at a lower excess bias voltage than in prior art devices (see “Background Art” section and FIG. 8) can be achieved via total avalanche breakdown or triggering probability enhancement in the depletion region. To be able to augment avalanche triggering probability, extensive numerical simulations on Technology Computer Aided Design (TCAD) were conducted, which enabled a design of a double-peaked electric field profile constituted in the same depletion region, where each peak corresponds to a distinct multiplication region, thereby giving the name to the region obtained by means of the method as double multiplication region configuration. The double multiplication region comprises two distinct multiplication regions. Thanks to these two separate multiplication regions, both the photogenerated electron and hole inside the depletion region can undergo avalanche multiplication. Furthermore, the photogenerated carriers created in the neutral substrate but diffusing to the depletion region have more chance to trigger an avalanche, owing to two distinct multiplication regions. The obtained double multiplication region configuration is in contrast to the prior art designed wide depletion and NIR enhanced SPADs, where the devices only have one multiplication region, and the magnitude of the electric field stays low in the remaining depletion region. Owing to this electric field engineering and designing a substrate non-isolated device, NIR PDP increases at lower excess bias voltages, while not sacrificing sensitivity in the visible spectrum. The maximum achievable NIR PDP is also enhanced if the pixel circuit allows for an increase in the excess bias voltage. The device has been fabricated in 110 nm CIS technology node and has an active area with a diameter of 10 μm.

### Device Design and TCAD Simulations

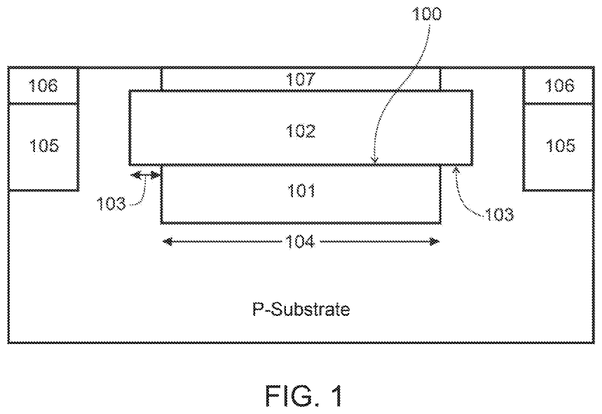

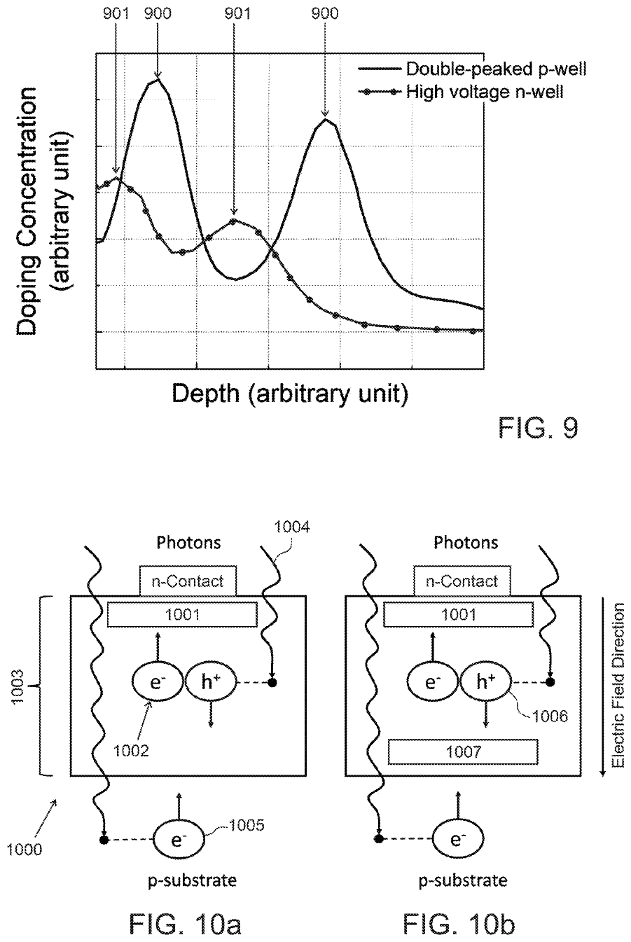

Referring to FIG. 1, a cross section of an example embodiment of the device according to the invention is shown, wherein the semi-conductor used may be silicon. In order to create two multiplication regions confined in the same depletion region that enhances the avalanche triggering probability of carriers, a technology-specific p-well layer 101/high-voltage n-well 102 main junction 100 is utilized corresponding to an active area 104, where the p-well layer 101 comprises a doping concentration distribution (not illustrated in FIG. 1), and first double peaks in the doping concentration distribution throughout the p-well layer 101 (first double peaks 900 illustrated in FIG. 9). Thanks to these first double peaks 900 in the p-well layer 101, n-p-n-p type doping profile is achieved (as illustrated in FIG. 9 with n-well high voltage second double peaks 901 and p-well first double peaks 900), which should form two distinct depletion and multiplication regions. However, these two depletion regions are merged since the n-doped region sandwiched between p-doped regions (this region corresponds to the second peak in the high-voltage n-well layer as indicated in FIG. 9) is short enough. Moreover, the high-voltage n-well layer 102 is extended to form a guard ring 103 around the main junction 100 and prevent the device from suffering premature edge breakdown. A high voltage to the device is applied between a P+ 106/high voltage p-well 105 anode electrode and an N+ cathode electrode 107.

### Double Multiplication Center in one Wide Depletion Region

The electric field inside the SPAD is engineered via the doping profile depicted in FIG. 9. In this configuration, the total doping concentration varies as n-p-n-p, which in fact should form two p-n junctions and depletion regions. The first intersection between the n and p layers should correspond to the first junction, and the third intersection should create the second one. However, it is expected that the electric field is going to decay when n-doping exceeds p-doping. If the second junction is located before the electric field reaches zero, then the two depletion regions, which have separate multiplication regions, should merge to form only one depletion region. This can be achieved provided that the n-doping and depth in the middle are suitable to not yield zero electric field before the second junction. Hence, it is possible that the second multiplication region in the same depletion zone can be achieved via this second peak in the doping layer 101. Having a second peak in the layer 101 that exceeds the n-doping is thereby necessary to achieve a second multiplication region. Therefore, in the resulting electric field profile of the device, a double peak is expected, where each peak basically corresponds to a distinct avalanche multiplication region, which renders the name of the method double multiplication region. This is in contrast to the design of any wide depletion region SPADs, where there is a single multiplication region. By inserting a second multiplication region into the same depletion region, the avalanche triggering probability, and thus the NIR sensitivity is significantly enhanced even at lower excess bias voltages.

As already mentioned above, the material for making the device is silicon and the technology is 110 nm CMOS Image Sensor (CIS). The high voltage may be for example around 3.3 V.

Various example size values for the device comprise 10 μm for the active junction diameter, and 16 μm from the left P+ region 106 to the right P+ region 106 in FIG. 1 (left and right correspond to left- and right-hand directions when reading the FIG. 1).

A width of the depletion region may for example be 1 μm.

### Electric Field and Avalanche Breakdown Probability

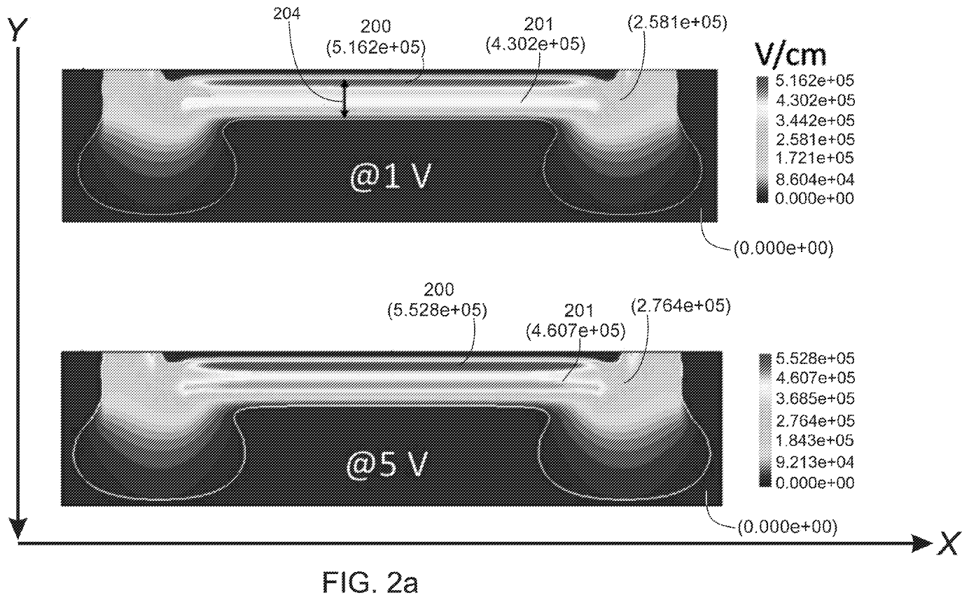

Electric field simulations of the device from FIG. 1 are shown in FIG. 2. The simulations were performed on TCAD numerical tool. Doping profiles (not shown in FIG. 1 or FIG. 2) of the layers used in the cross section of FIG. 1 were imported into the simulation environment. An example of doping profiles is illustrated in FIG. 9 containing a graph of doping concentration as a function of depth, comprising curves labeled “Double-peaked p-well” and “High voltage n-well”. Then, coupled Poisson and electron-hole drift-diffusion equations were solved to calculate the electric field magnitude under various voltages. As illustrated in FIG. 2(a), in addition to the first electric field peak indicated with first tone 200, the second peak appears in the proposed device's field profile at 1 V excess bias, which is depicted with second tone 201. The variation of the electric field from 1 V to 5 V excess bias voltage is also given, where the second peak becomes more obvious with its emerging first tone 200. Besides, the magnitude of the electric field at the center of the device of FIG. 1 along the y axis from 1 V to 5 V excess bias is provided in FIG. 2(b). It demonstrates that the electric field profile indeed has double peaks 202 and 203 (see FIG. 2(c)) that are confined in one depletion region whose boundaries are shown by the arrow 204 in FIG. 2(b). Each peak 202 and 203 is above the critical avalanche breakdown field in silicon, which is 3×10⁵ V/cm, and corresponds to a different multiplication region. Therefore, the second peak 203 will behave as a second multiplication center for the carriers, which is a new concept for SPAD design and can be utilized in any CMOS technology. Hence, the electric field simulations prove that two multiplication regions are inserted into one wide depletion region. A second multiplication region does not exist in the other designed SPADs so far, an example of which is simulated, and its electric field profile 205 is illustrated in FIG. 2(b) and FIG. 2(c), which show that only one peak that corresponds to only one multiplication region exists in those devices. The cross section of this example SPAD is provided in FIG. 2(d), which was adapted from Ref. [6] and has a similar depletion region width with the proposed device designed with the double multiplication region method. The depletion widths of both devices are indicated by the arrows 204 in FIG. 2(a) and 2(b).

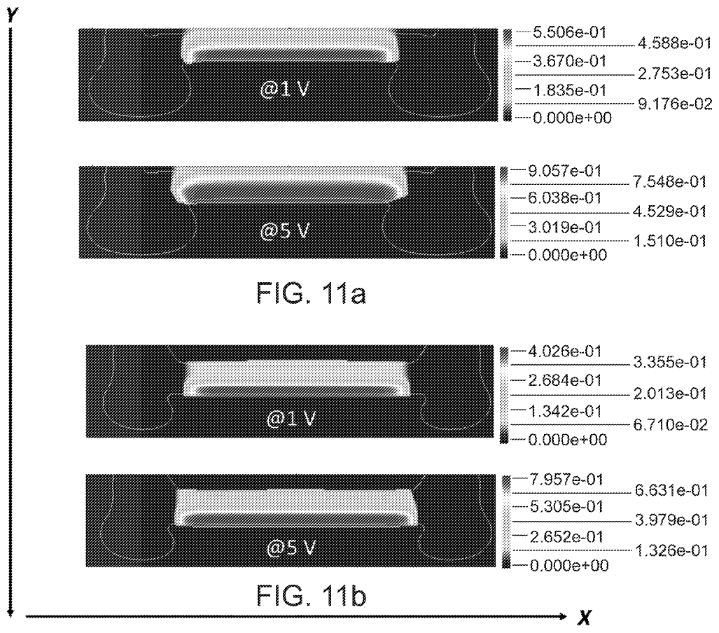

One advantage of this new SPAD electric field profile that has two separated multiplication regions in a wide depletion region is that the total avalanche triggering probability of the photogenerated carriers is increased, thus enhancing the NIR sensitivity of the devices and reaching a high NIR PDP at a relatively lower excess bias voltage. The advantage is conceptualized in FIG. 10. FIG. 10(a) represents a wide depletion region SPAD 1000 with one multiplication region 1001. As illustrated in this scheme, when an electron-hole pair 1002 is generated in the middle of a depletion region 1003 upon the absorption of a photon 1004, only a photogenerated electron (e⁻) 1002 can trigger an avalanche, whereas a hole (h⁺) travels to the substrate. Moreover, the photogenerated electron 1005 created in the neutral substrate of the depletion region 1003 and diffusing to the depletion has only one chance to trigger an avalanche due to the one multiplication region 1001. On the other hand, FIG. 10(b) indicates a device designed with the double multiplication region method. It shows that a photogenerated hole (h⁺) 1006 in the middle of the depletion region 1003 can also trigger an avalanche, thanks to a second multiplication region 1007 inserted. In addition, diffusing photogenerated electrons from the substrate can now have up to two times chance of triggering an avalanche as well. Hence, it is guaranteed to boost the total avalanche breakdown probability and the NIR PDP of the SPAD with the double multiplication region method. The disadvantage is that the concept is also valid for the carriers generated thermally or via tunneling, which increases the noise of the SPADs.

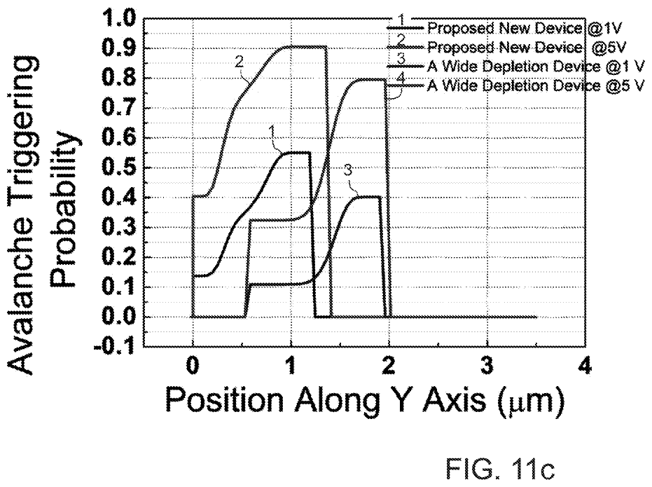

To prove the claim of enhanced avalanche breakdown probability expected with the double multiplication region method, breakdown probabilities of the proposed device with two multiplication regions and the same example wide depletion region device with one multiplication region are simulated, as given in FIG. 11(a) and FIG. 11(b), respectively. The total avalanche triggering probability obtained for the wide depletion region SPAD example is 33% in the middle of the device, whereas it reaches 77% in the proposed SPAD, as can be observed from FIG. 11(c), thanks to the existence of the second multiplication region. Furthermore, if an absorption outside the depletion region is considered, which is likely to happen at the NIR wavelengths, the photogenerated electrons that are going to diffuse to the depletion region have 1.2 times more probability to trigger an avalanche, as calculated from the edge of the depletion regions. Thus, operating double multiplication region devices at lower excess bias voltages is possible to achieve similar or higher NIR PDPs as in conventional wide depletion region SPADs with only one multiplication region.

### Characterization Results

### I-V Measurements and Light Emission Tests

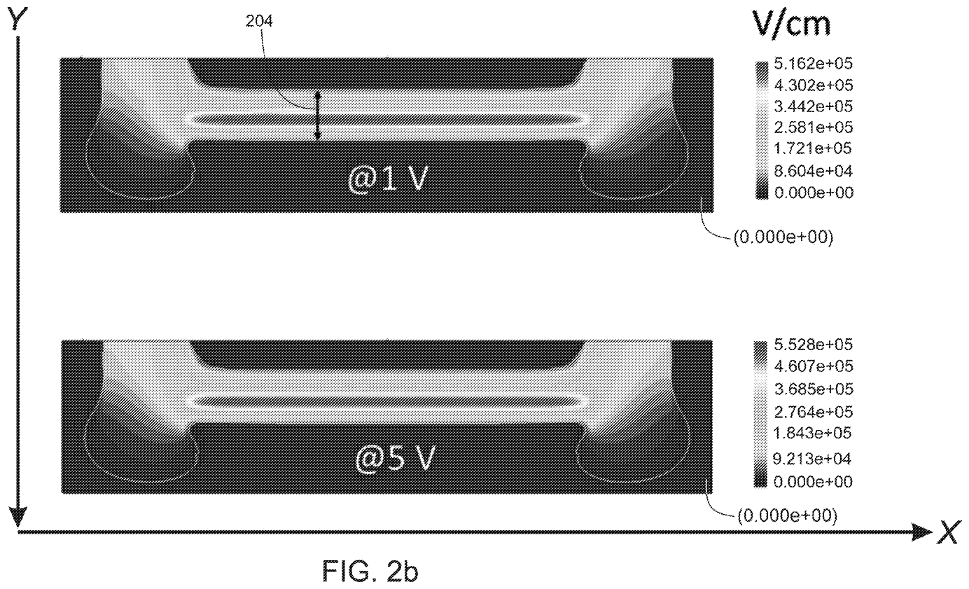

FIG. 3(a) shows the I-V characteristics of the device from FIG. 1 under ambient light and at room temperature. The breakdown voltage, which is displayed by the sharp increase in the current, occurs at 29.8 V. To verify that the device does not suffer from premature edge breakdown, light emission tests were performed at 3 V and 5 V excess bias voltages. FIG. 3(b) shows that there is no edge breakdown effect in the proposed device, thanks to the implemented guard ring structure in the design. These results prove that the device functions properly in Geiger mode.

### DCR Measurements

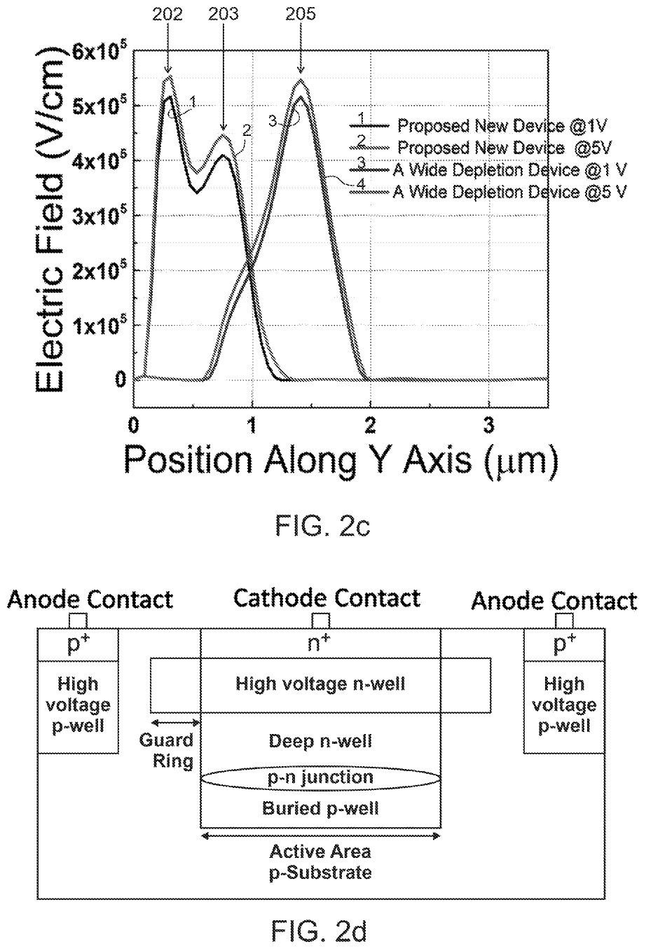

The DCR measurements were taken with an externally connected 660 kilo-ohm resistor to quench and recharge the SPADs. The same SPAD is measured from different dies to collect statistics about the noise. FIG. 4 demonstrates the DCR measurements belonging to five devices with respect to the excess bias voltage. According to this graph, Device 3 was selected as a reference since it corresponds to the median in the noise measurements. The DCR of this device changes from 8 cps at 1 V to 295 cps at 5.5 V excess bias and at room temperature. Accordingly, the DCR per unit area at 5.5 V excess becomes 3.7cps/μm² . In the following, the characterization results of Device 3 will be presented.

### Afterpulsing Probability Measurement

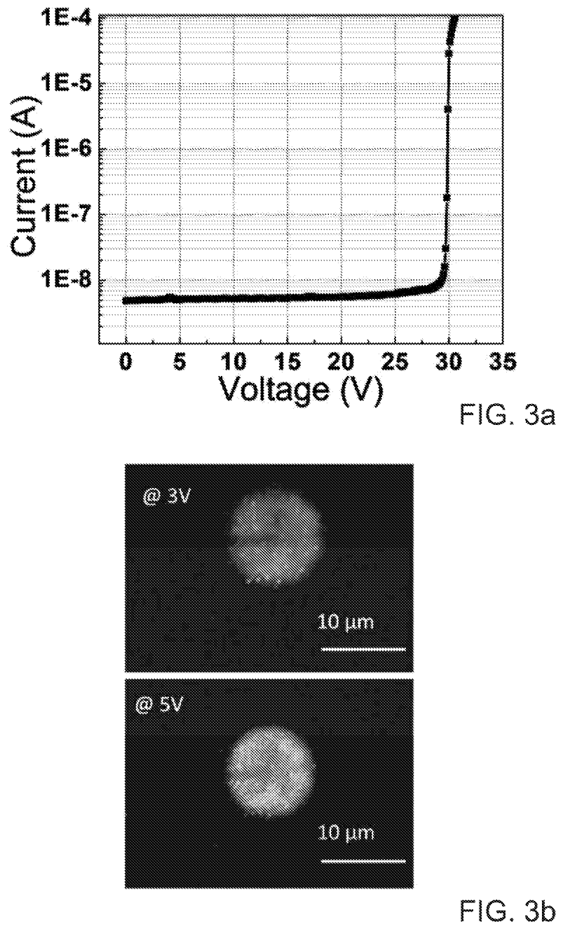

The afterpulsing histogram of the device was obtained with the inter-avalanche time method. To measure the time interval between the pulses, a high-speed digital oscilloscope (Tele-dyne LeCroy WavePro 760Zi-A) was utilized. An afterpulsing histogram obtained under dim light is shown in FIG. 5. Histogram 500 corresponds to a measured pulse inter-arrival time histogram, and curve 501 is a fit curve. As the SPAD was passively quenched and recharged through an external resistor, the dead time of the SPAD was around 7 μs. The afterpulsing probability of the device is 5.4% at 5.5 V excess bias, which is calculated as the ratio of the area between the measured and fitted curves to the area beneath the fitted curve. Hence, this low afterpulsing probability indicates that the defect concentration in the fabricated device is likewise expected to be low.

### Photon Detection Probability Measurements

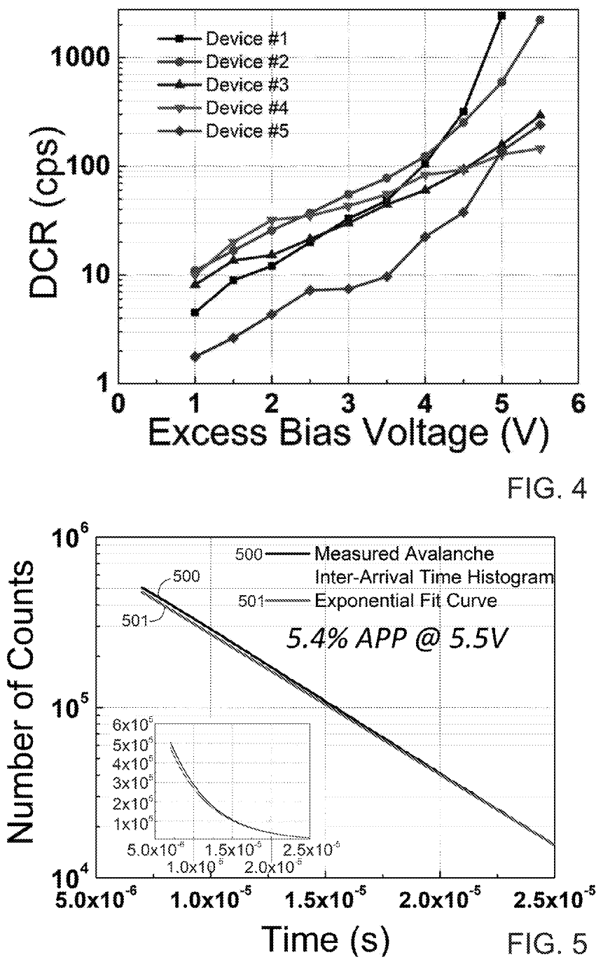

The PDP of the device was measured via a monochromator setup where a Xenon lamp emits broad-band light and a monochromator selects each wavelength through the gratings. Then, an integrating sphere was used to provide spatially uniform light onto the SPAD and a calibrated reference detector to precisely assess the impinging photon count. Under this configuration, the measured PDP of the device was obtained as shown in FIG. 6, from 1 V to 5.5 V excess bias voltage. As is more obvious at 5.5 V, the peak PDP actually occurs at two different wavelengths, which are 450 nm and 500 nm. It is believed that this is related to the two-peak nature of the electric field profile of the device, which thereby forms two multiplication regions favoring the detection of these wavelengths the most. At an excess bias voltage of 4 V and 500 nm wavelength, the device has a PDP of 50%, and at 5.5 V excess, PDP at 500 nm reaches 78%. Furthermore, thanks to the second multiplication region inserted into a wide depletion region and keeping the substrate non-isolated from the junction, NIR sensitivity of the device is also enhanced. At 850 nm, the SPAD has a PDP of 13% and 25.5% only at 4 V and 5.5 V excess bias voltages, respectively.

### Jitter Measurement

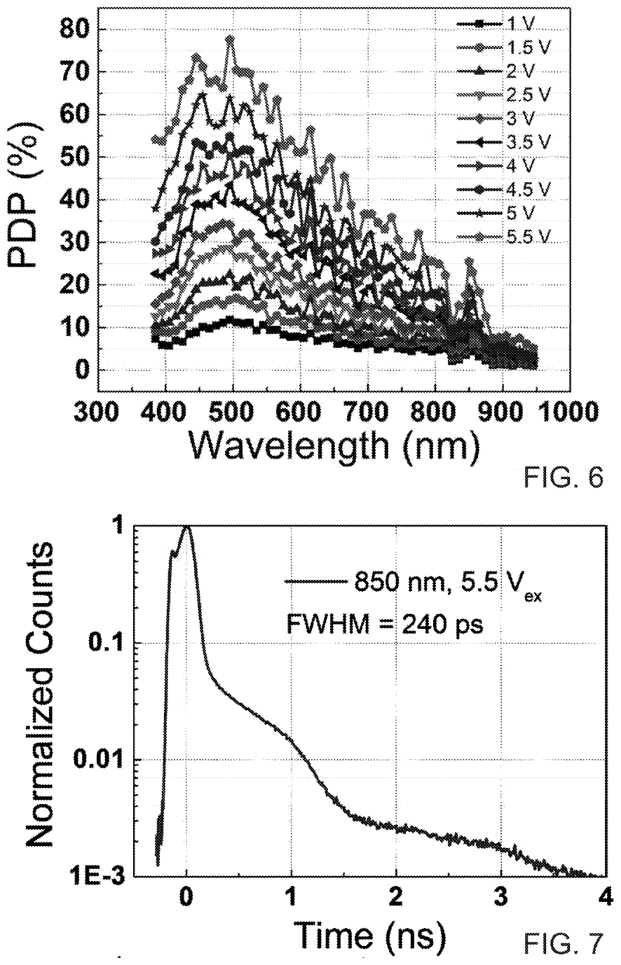

To measure the timing jitter, the time-correlated single-photon counting (TCSPC) technique was employed. The device was illuminated with a 850 nm (A.L.S. GmbH) pulsed laser operating at 100 kHz, and incident power was reduced to single-photon regime with the absorptive neutral density filters. To detect the time difference between the laser clock signal and the positive edge of each avalanche pulse, the same high-speed digital oscilloscope was used. The jitter histograms acquired at 850 nm and at 5.5 V excess biases are provided in FIG. 7. The jitter is calculated as full width at half maximum (FWHM), which is 240 ps at 5.5 V excess bias voltage. Since many of the diffused carriers from the substrate reached the depletion region due to the substrate non-isolated structure, two peaks in the timing jitter were observed. The smaller peak is the contribution of the carriers generated in the depletion region, and the other peak represents the contribution of the diffused carriers.

### Comparison with State-of-the-Art

In FIG. 8, the best-performing front-side-illuminated (FSI) CMOS SPADs having a wide depletion and NIR enhanced sensitivity is chosen to compare the device 3 mentioned hereinabove with. FIG. 8(a) indicates the peak PDP achieved with these SPADs versus the normalized DCR with the active areas. As can be seen, the device 3 attains the highest PDP ever reported among these FSI wide depletion region SPADs. The noise of the device 3 in terms of DCR per unit area also matches with most of the state-of-the-art SPADs. FIG. 8(b) shows the PDP comparison at 850 nm wavelength with respect to the excess bias voltage. It demonstrates that device 3 indeed eliminates the high excess bias needed in wide depletion devices, owing to inserting a second multiplication region into the same wide depletion region in this work that increases the total avalanche triggering probability. FIG. 8(b) also illustrates that device 3 reaches one of the highest PDPs at NIR.

### Conclusion

A new technique, named double multiplication region, was proposed to achieve high NIR PDP in the wide depletion region SPADs at relatively lower excess bias voltages. As opposed to the conventional wide depletion devices that have only one multiplication region, the technique aims at inserting a second multiplication region. As demonstrated in the avalanche breakdown probability simulations in TCAD in FIG. 11(a)-11(c), second multiplication region increases the triggering probability significantly. The reason for this increase is also explained in FIG. 10(a)-10(b). To achieve the second multiplication region, a double-peaked p-well was used in junction with the high-voltage n-well layer, where two peaks result in two p-n junctions and, consequently, two multiplication regions. Between these two peaks, n-doping exceeds p-doping to cause electric field decay and separate the two distinct multiplication regions, as shown in FIG. 9. The characterization results of this device indicate that high PDPs at NIR can indeed be obtained at 5.5 V excess bias voltage, reaching 25.5% at 850 nm while keeping the noise at an acceptable level of 295 cps. The high NIR PDP was achieved thanks to the substrate-non-isolated and wide depletion region SPAD structure, with a higher breakdown probability for the carriers. Reducing the need for high excess bias voltages was addressed owing to the enhanced avalanche triggering probabilities at a given excess bias. However, the jitter of the SPAD deteriorated to 236 ps due to the detected diffused carriers from the substrate.

### REFERENCES

[1] K. Morimoto, A. Ardelean, M.-L. Wu, A. C. Ulku, I. M. Antolovic, C. Bruschini, and E. Charbon, “Megapixel time-gated spad image sensor for 2d and 3d imaging applications,” Optica, vol. 7, no. 4, pp. 346-354, 2020.
[2] J. M. Pavia, M. Scandini, S. Lindner, M. Wolf, and E. Charbon, “A 1×400 backside-illuminated spad sensor with 49.7 ps resolution, 30 pj/sample tdcs fabricated in 3d cmos technology for near-infrared optical tomography,” IEEE Journal of Solid-State Circuits, vol. 50, no. 10, pp. 2406-2418, 2015.
[3] M. T. Rakher, L. Ma, O. Slattery, X. Tang, and K. Srini-vasan, “Quantum transduction of telecommunications-band single photons from a quantum dot by frequency upconversion,” Nature Photonics, vol. 4, no. 11, pp. 786-791, 2010.
[4] M. Moreno-García, H. Xu, L. Gasparini, and M. Peren-zoni, “Low-noise single photon avalanche diodes in a 110 nm cis technology,” in 2018 48th European Solid-State Device Research Conference (ESSDERC). IEEE, 2018, pp. 94-97.
[5] I. Vornicu, J. M. Lopez-Martinez, F. N. Bandi, R. C. Galan, and A. Rodriguez-Vazquez, “Design of high-efficiency spads for lidar applications in 110 nm cis technology,” IEEE Sensors Journal, vol. 21, no. 4, pp. 4776-4785, 2020.
[6] E. A. Webster, L. A. Grant, and R. K. Henderson, “A high-performance single-photon avalanche diode in 130-nm cmos imaging technology,” IEEE Electron Device Letters, vol. 33, no. 11, pp. 1589-1591, 2012.
[7] M. Sanzaro, P. Gattari, F. Villa, A. Tosi, G. Croce, and F. Zappa, “Single-photon avalanche diodes in a 0.16 μm bcd technology with sharp timing response and red-enhanced sensitivity,” IEEE Journal of Selected Topics in Quantum Electronics, vol. 24, no. 2, pp. 1-9, 2017.
[8] F. Gramuglia, P. Keshavarzian, E. Kizilkan, C. Bruschini, S. S. Tan, M. Tng, E. Quek, M.-J. Lee, and E. Charbon, “Engineering breakdown probability profile for pdp and dcr optimization in a spad fabricated in a standard 55 nm bcd process,” IEEE Journal of Selected Topics in Quantum Electronics, vol. 28, no. 2: Optical Detectors, pp. 1-10, 2021.
[9] M. Ghioni, A. Gulinatti, I. Rech, F. Zappa, and S. Cova, “Progress in silicon single-photon avalanche diodes,” IEEE Journal of selected topics in quantum electronics, vol. 13, no. 4, pp. 852-862, 2007.
[10] C. Veerappan and E. Charbon, “A low dark count pin diode based spad in cmos technology,” IEEE transactions on electron devices, vol. 63, no. 1, pp. 65-71, 2015.
[11] A. Gulinatti, I. Rech, F. Pazeri, C. Cammi, P. Maccagnani, M. Ghiono, and S. Cova, “New silicon spad technology for enhanced red-sensitivity high-resolution timing and system integration,” Journal of Modern Optics, vol. 59, no. 17, pp. 1489-1499, 2012.

1. A near-infrared sensitivity enhanced substrate non-isolated silicon single-photon avalanche diode, comprising
a p-well layer (101),
a high-voltage n-well (102),
the p-well layer (101) and the high-voltage n-well layer (102) positioned against each other and configured to form a main junction (100) defining an active area (104),
the p-well layer (101) comprising a doping according to a doping concentration distribution,
the p-well layer (101) being configured to have first double peaks (900) in its doping concentration distribution throughout the p-well layer in the active area (104), corresponding to respective p-doped regions, and the high-voltage n-well (102) being configured to have second double peaks (901), corresponding to respective n-doped regions configured to achieve a n-p-n-p type device junction profile,
whereby further the p-well layer is lightly doped and configured to obtain a wide depletion region, i.e., at least 1 μm wide,
the high-voltage n-well layer (102) being further configured to extend beyond the p-well layer (101) to form a guard ring (103) around the active area (104).

2. The near-infrared sensitivity enhanced substrate non-isolated silicon single-photon avalanche diode of claim 1, wherein
the n-p-n-p type device junction profile is further configured such that
the wide depletion region confines two distinct multiplication regions, and
one of the n-doped regions is sandwiched between the p-doped regions, and has a well-designed doping concentration and depth configured such that an electric field between the two p-n junctions never reaches zero.
